(19) United States
(12) Patent Application Publication
(10) Pub. No.: US 2007/0197014 A1
(43) Pub. Date: Aug. 23, 2007

(54) Method of fabricating semiconductor device

(75) Inventors: Jin-ho Jeon, Seoul (KR); Cha-won Koh, Yongin-si (KR); Yun-sook Chae, Suwon-si (KR); Gi-sung Yeo, Seoul (KR); Tae-young Kim, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/702,841

(22) Filed: Feb. 6, 2007

(30) Foreign Application Priority Data
Feb. 17, 2006 (KR) 10-2006-0015793

(51) Int. Cl. H01L 21/44

(52) U.S. Cl. 438/597

(57) ABSTRACT

A method of fabricating a semiconductor device includes forming an interlayer insulating layer on a semiconductor substrate, forming a hard mask layer on the interlayer insulating layer, forming a hard mask pattern in which a plurality of contact hole patterns are formed by patterning the hard mask layer at least two times, conformally forming a supporting liner layer on the hard mask pattern, which supports the hard mask pattern during etching by reinforcing the thickness of the hard mask pattern, forming a plurality of contact hole patterns in the interlayer insulating layer using the hard mask pattern on which the supporting liner layer is formed as an etching mask, and forming contact plugs filling the plurality of contact hole patterns.

### CROSS-REFERENCE TO RELATED APPLICATION

This application claims priority under 35 U.S.C. §119 to Korean Patent Application No. 10-2006-0015793 filed on Feb. 17, 2006, in the Korean Intellectual Property Office, the disclosure of which is incorporated herein in its entirety by reference.

### BACKGROUND OF THE INVENTION

1. Field of the Invention

The present invention relates to a method of fabricating a semiconductor device, and more particularly, to a method of fabricating a semiconductor device, by which a contact can be stably formed within an interlayer insulating layer.

2. Description of the Related Art

With increases in the integration density of semiconductor devices, the width of a contact that connects a lower conductive layer and an upper interconnection decreases. A pitch between contact hole patterns also decreases. To reduce the size of a contact hole pattern and a pitch between contact hole patterns, thermal reflow, resolution enhancement of lithography by assist of chemical shrinkage (RELACS), shrink assist layer for enhanced resolution (SAFIER), or ArF plasma processing is applied to a photoresist pattern.

However, it is difficult to implement a photoresist pattern having sufficiently large thickness when a short-wavelength light source such as ArF is used. Moreover, since the photoresist pattern does not have sufficiently high resistance to etching, it cannot perform a role as an etching mask very well when an etching depth is deep like in an interlayer insulating layer. To solve the problem, instead of the photoresist pattern, a hard mask layer having superior etching-resistance is used as an etching mask.

However, to reduce the size of a contact hole pattern or a distance between contact hole patterns, the thickness of a hard mask layer also decreases. The hard mask layer having a reduced width can collapse because of its low resistance to etching. As a result, cracking can occur between adjacent contact hole patterns, causing degradation in the characteristics of a semiconductor device such as short-circuits between contacts.

### SUMMARY OF THE INVENTION

In accordance with various aspects of the present invention provided is a method of fabricating a semiconductor device, by which a short-circuit phenomenon between contacts is prevented by forming a contact hole pattern stably, thereby improving the characteristics of a semiconductor device.

According to an aspect of the present invention, there is provided a method of fabricating a semiconductor device. The method includes forming an interlayer insulating layer on a semiconductor substrate, forming a hard mask layer on the interlayer insulating layer, forming a hard mask pattern in which a plurality of contact hole patterns are formed by patterning the hard mask layer at least two times, conformally forming on the hard mask pattern a supporting liner layer that supports the hard mask pattern during etching by reinforcing the thickness of the hard mask pattern, forming a plurality of contact hole patterns in the interlayer insulating layer using the hard mask pattern in which the supporting liner layer is formed as an etching mask, and forming contact plugs filling the plurality of contact hole patterns.

The forming of the hard mask layer can comprise forming a hard mask layer having a multi-layered structure on the interlayer insulating layer.

The forming of the hard mask layer can comprise forming a silicon oxide layer, a silicon nitride layer, a silicon oxy-nitride layer, or an amorphous carbon layer.

The supporting liner layer can be formed using atomic layer deposition (ALD) or plasma enhanced chemical vapor deposition (PECVD).

The contact hole patterns can be formed with a width of about 50 nm or less.

The contact hole patterns can be formed such that a distance between the contact hole patterns is about 50 nm or less.

The forming of the hard mask pattern can comprise: forming a plurality of first contact hole patterns that are separated by a predetermined distance from each other by performing a first patterning process; and forming second contact hole patterns between the first contact hole patterns by performing a second patterning process.

The forming of the hard mask pattern can comprise: forming a first anti-reflective layer on the hard mask layer; forming on the anti-reflective layer a first photoresist pattern that exposes the top of the anti-reflective layer and has the first contact hole pattern formed therein; forming the plurality of first contact hole patterns separated by a predetermined distance in the hard mask layer using the first photoresist pattern as an etching mask; removing the first photoresist pattern and the first anti-reflective layer, and forming a second anti-reflective layer covering the hard mask layer in which the first contact hole pattern is formed; forming a second photoresist pattern that exposes the top of the second anti-reflective layer and in which the second contact hole patterns interspersed with the plurality of first contact hole patterns are formed; and forming the second contact hole pattern in the hard mask layer in which the first contact hole patterns are formed using the second photoresist pattern as an etching mask.

According to another aspect of the present invention, there is provided a method of fabricating a semiconductor device. The method includes forming an interlayer insulating layer on a semiconductor substrate, forming a hard mask layer having a multi-layered structure on the interlayer insulating layer, forming a top mask pattern layer in which a plurality of contact hole patterns are formed by patterning the top layer of the hard mask layer at least two times, conformally forming on the top mask pattern layer a supporting liner layer that supports the top mask pattern layer during etching by reinforcing the thickness of the top mask patter layer, completing the hard mask pattern having the multi-layered structure by patterning the top mask pattern layer in which the supporting liner layer is formed using an etching mask, forming a plurality of contact hole patterns in the interlayer insulating layer using the hard mask pattern using an etching mask, and forming contact plugs that fill the plurality of contact hole patterns.

The forming of the hard mask layer can comprise forming a silicon oxide layer, a silicon nitride layer, a silicon oxy-nitride layer, or an amorphous carbon layer.

The forming of the supporting liner layer can comprise forming the supporting liner layer using atomic layer deposition (ALD) or plasma enhanced chemical vapor deposition (PECVD).

The forming of the contact hole patterns can comprise forming the contact hole patterns with a width of about 50 nm or less.

The forming of the contact hole patterns can comprise forming the contact hole patterns such that a distance between the contact hole patterns is about 50 nm or less.

The forming of the top mask pattern layer can comprise: forming a plurality of first contact hole patterns separated by a predetermined distance by performing a first patterning process on the top layer of the hard mask layer; and forming second contact hole patterns between the plurality of first contact hole patterns by performing a second patterning process on the top layer of the hard mask layer in which the first contact hole patterns are formed.

The forming of the top hard mask pattern can comprise: forming a first anti-reflective layer on the top layer of the hard mask layer; forming on the first anti-reflective layer a first photoresist pattern that exposes the top of the first anti-reflective layer and in which the first contact hole patterns are formed; forming the plurality of first contact hole patterns separated by a predetermined distance in the top layer of the hard mask layer using the first photoresist pattern as an etching mask; removing the first photoresist pattern and the first anti-reflective layer; forming a second anti-reflective layer covering the top layer of the hard mask layer in which the first contact hole patterns are formed; forming a second photoresist pattern that exposes the top of the second anti-reflective layer and in which second contact hole patterns interspersed with the first contact hole patterns are formed; and forming the second contact hole pattern in the top layer of the hard mask layer in which the first contact hole patterns are formed using the second photoresist pattern as an etching mask.

### BRIEF DESCRIPTION OF THE DRAWINGS

The drawing figures depict preferred embodiments by way of example, not by way of limitation. In the figures, like reference numerals refer to the same or similar elements, in which:

FIGS. 1A through 1K are cross-sectional views sequentially illustrating an embodiment of a method of fabricating a semiconductor device according to an aspect of the present invention; and

FIGS. 2A through 2L are cross-sectional views sequentially illustrating another embodiment of a method of fabricating a semiconductor device according to another aspect of the present invention.

### DETAILED DESCRIPTION OF PREFERRED EMBODIMENTS

Advantages and features of the present invention and methods of accomplishing the same can be understood more readily by reference to the following detailed description of preferred embodiments and the accompanying drawings. The present invention can, however, be embodied in many different forms and should not be construed as being limited to the embodiments set forth herein. Like reference numerals refer to like elements throughout the specification.

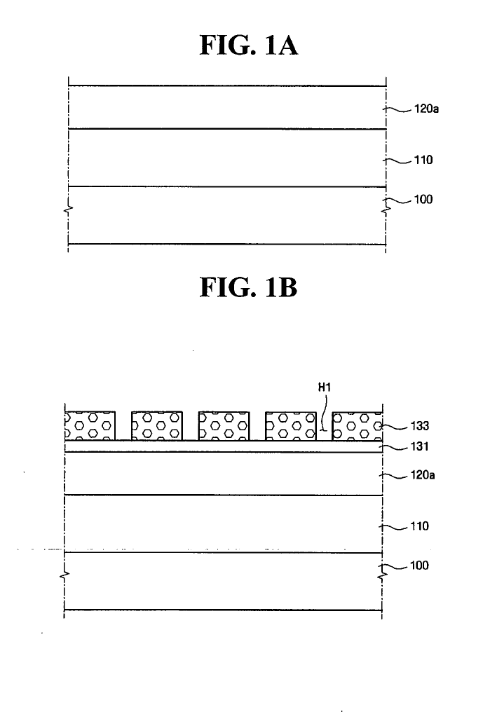

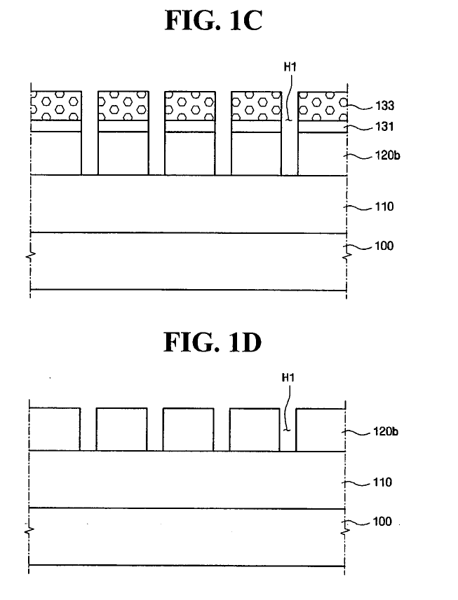

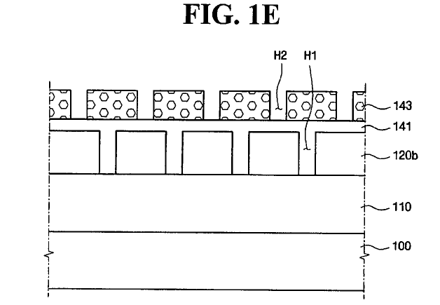

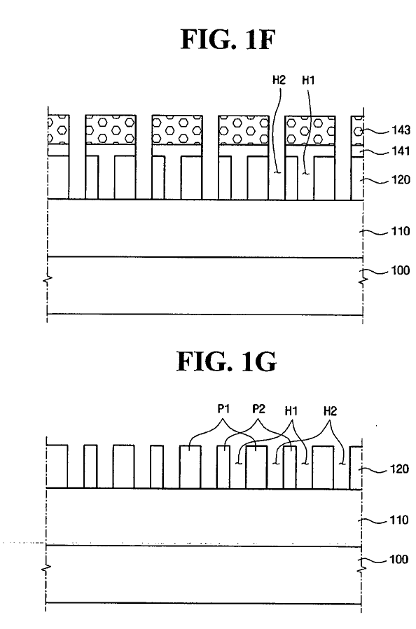

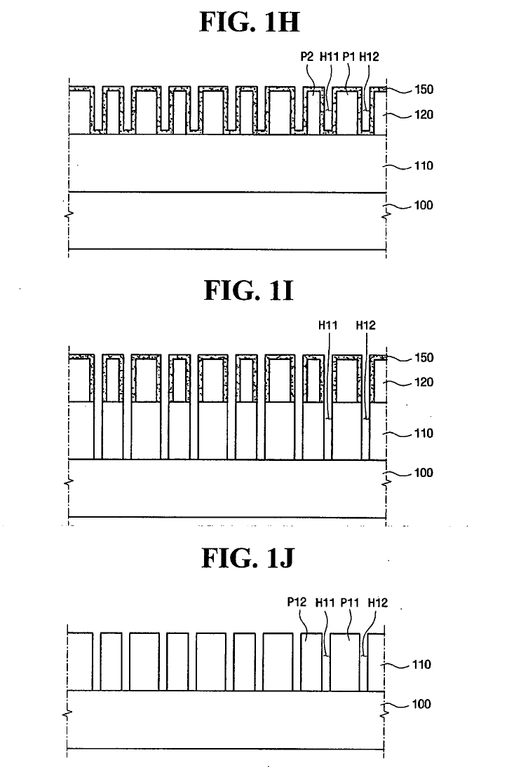

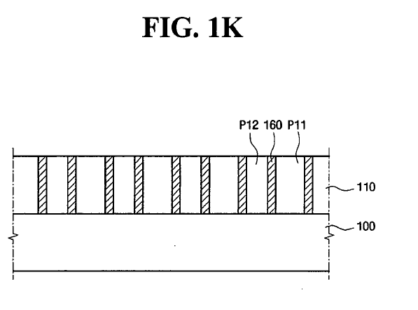

Hereinafter, an embodiment of a method of fabricating a semiconductor device according to an aspect of the present invention will be described in detail with reference to FIGS. 1A through 1K.

Referring to FIG. 1A, an interlayer insulating layer 110 and a hard mask layer 120a are sequentially formed on a semiconductor substrate 100. Here, the semiconductor substrate 100 can be, for example, a substrate made of at least one semiconductor material selected from a group comprising of Si, Ge, Si—Ge, GaP, GaAs, SiC, SiGeC, InAs and InP, or a SOI (silicon on insulator) substrate. Also, although not shown in the figures, various unit devices, such as a transistor, can be formed on the semiconductor substrate 100.

The interlayer insulating layer 110 can be a silicon oxide (SiOx) layer, a Plasma Enhanced TetraEthylOrthoSilicate (PE-TEOS) layer, a Plasma Enhanced OXide (PEOX) layer, a Fluoride Silicate Glass (FSG) layer, a PhosphoSilicate Glass (PSG) layer, a BoroPhosphoSilicate Glass (BPSG) layer, an Undoped Silicate Glass (USG) layer, or a stacked layer of two or more of the foregoing. In the present invention, the interlayer insulating layer 110 can be formed with a thickness of about 6000-7000 Å, but larger or smaller thicknesses can be used.

The hard mask layer 120a in which a mask pattern for forming a contact hole pattern within the interlayer insulating layer 110 is to be formed can be a single layer formed of a silicon oxide layer, a silicon nitride layer, a silicon oxy-nitride layer, or a amorphous carbon layer or a stacked layer of two or more of the foregoing. In the present invention, the hard mask layer 120a can be formed with a thickness of about 1200-1500 Å, but larger or smaller thicknesses can be used depending on the thickness or material of the interlayer insulating layer 110 to be etched.

Referring to FIG. 1B, a first anti-reflective layer 131 and a first photoresist pattern 133 are formed on the hard mask layer 120a. The first photoresist pattern 133 is used to transmit a contact hole pattern to the hard mask layer 120a, in which a first contact hole pattern H1 is formed. The first contact hole pattern H1 can be formed with a width of about 50 nm or less, but its width can be increased or decreased in different embodiments.

To reduce the width of the first contact hole pattern H1, the first photoresist pattern 133 can be processed by thermal reflow, resolution enhancement of lithography by assist of chemical shrinkage (RELACS), shrink assist film for enhanced resolution (SAFIER), or ArF plasma processing, as examples.

As illustrated in FIG. 1C, the hard mask layer (120a of FIG. 1B) is patterned using the first photoresist pattern 133 as an etch mask. Thus, a pattern that is the same as the first contact hole pattern H1 of the first photoresist pattern 133 is formed on the hard mask layer 120b.

Here, the hard mask layer can be patterned by a well-known dry etching method.

As illustrated in FIG. 1D, the first photoresist pattern (133 of FIG. 1C) and the first anti-reflective layer (131 of FIG. 1C) are removed. The removal can be performed by a general ashing and strip process.

As illustrated in FIG. 1E, the first contact hole pattern H1 is filled to form a second anti-reflective layer 141 covering the hard mask layer 120b, and a second photoresist pattern 143 for forming a second contact hole pattern H2 is formed on the second anti-reflective layer 141 in the manner described above. Here, the second contact hole pattern H2 can be positioned to cover holes formed in the first contact hole patterns H1 formed on the hard mask layer 120b.

As illustrated in FIG. 1F, the second contact hole pattern H2 is further formed on the hard mask layer using the second photoresist pattern 143 as an etch mask, thereby completing a hard mask pattern 120 in which the first contact hole patterns H1 and the second contact hole patterns H2 are formed.

As illustrated in FIG. 1G, the second photoresist pattern 143 and the second anti-reflective layer 141 are removed by a general ashing and strip process, for example, thereby exposing the hard mask pattern 120 in which the first contact hole patterns H1 and the second contact hole patterns H2 are interspersed with each other, e.g., in an alternating pattern.

Referring to FIG. 1G, the first contact hole pattern H1 and the second contact hole pattern H2 can be formed with a width of about 50 nm or less, and can be interspersed by a predetermined distance. The distance between the first contact hole pattern H1 and the second contact hole pattern H2, i.e., the width of a first pattern P1 or a second pattern P2 that is the hard mask pattern 120 formed between the first contact hole pattern H1 and the second contact hole pattern H2, can be about 50 nm or less.

As such, since a hard mask pattern can be formed by a plurality of patterning processes, reduction in the pitch of a fine pattern can be achieved, which has been difficult to implement with the existing performance of an exposure device. Although patterning two times is taken as an example in the current embodiment, patterning three or more times can be performed in other embodiments.

As shown in FIG. 1G, the distance between the first contact hole pattern H1 and the second contact hole pattern H2 need not be uniform, which can be intentional due to the characteristics of a semiconductor device or can be caused by misalignment during formation of the second contact hole pattern H2. Thus, the hard mask pattern 120 can be formed of patterns having different thicknesses like the first pattern P1 and the second pattern P2. Here, the first pattern P1 can be formed with a thickness that is large enough for the first pattern P1 to have sufficiently high resistance to an etching process, but the second pattern P2 can be formed with a thickness that is so small that the second pattern P2 can be vulnerable to collapse during a subsequent etching process.

Referring to FIG. 1H, a supporting liner layer 150 can be formed conformally inside the first contact hole pattern H1 and the second contact hole pattern H2 and on the hard mask pattern 120. Since the supporting liner layer 150 can reinforce the thickness of the sidewalls of the hard mask pattern 120, a portion having a small thickness such as the second pattern P2, can be prevented from collapsing during a subsequent etching process.

The supporting liner layer 150 can be formed at low temperature using atomic layer deposition (ALD) or plasma enhanced chemical vapor deposition (PECVD) and with a thickness of about 50-500 Å, as an example. However, different thicknesses are possible within the scope of the present invention.

The material of the supporting liner layer 150 can be selected according to the material of a layer to be etched under the hard mask pattern 120 and can be, for example, an oxide layer or a nitride layer. The supporting liner layer 150 can be formed of the same material as a layer to be etched under the hard mask pattern 120, for example, an oxide layer or a nitride layer. When the interlayer insulating layer 110 is an oxide layer, the supporting liner layer 150 can also be an oxide layer.

First and second contact hole patterns H11 and H12 formed by the supporting liner layer 150 can have relatively small widths. As illustrated in FIG. 1I, the interlayer insulating layer 110 is patterned using the hard mask pattern 120 in which the supporting liner layer 150 is formed as an etch mask. Here, since its sidewall thickness has been reinforced, the hard mask pattern 120 can be prevented from collapsing with the aid of the supporting liner layer 150, the first contact hole patterns H11 and the second contact hole patterns H12 can be formed stably in the interlayer insulating layer 110. In other words, cracking between the first and second contact hole patterns H11 and H12 can be prevented.

Referring to FIG. 1J, the interlayer insulating layer 110 can be exposed by removing the hard mask pattern 120 using a generally known method.

As shown in FIG. 1J, the first contact hole patterns H11 and the second contact hole patterns H12 formed in the interlayer insulating layer 110 have smaller widths than the first contact hole pattern H1 and the second contact hole pattern H2 of FIG. 1G formed in the hard mask pattern 120 of FIG. 1G. Interlayer insulating layer patterns P11 and P12 formed between the first contact hole patterns H11 and the second contact hole patterns H12 have larger widths than the first patterns P1 and the second patterns P2 of FIG. 1G of the hard mask pattern 120 of FIG. 1G. This is because the sidewalls of the hard mask pattern 120 are reinforced by the supporting liner layer 150 prior to etching of the interlayer insulating layer 110. Thus, a finer contact hole pattern can be formed in the interlayer insulating layer 110.

Referring to FIG. 1K, a plurality of formed contact hole patterns are filled with a conductive material to form contact plugs 160, thereby completing a contact in the interlayer insulating layer 110. Short-circuits between the contact plugs 160 can be minimized by preventing cracking between contact hole patterns, thereby avoiding degradation in the characteristics of a semiconductor device formed in accordance with the above embodiment.

A semiconductor device can be completed by forming interconnections for enabling input/output of an electric signal, forming a passivation layer on a substrate, and packaging the substrate, in accordance with processes known in the art. These processes, being generally known, will not be described herein.

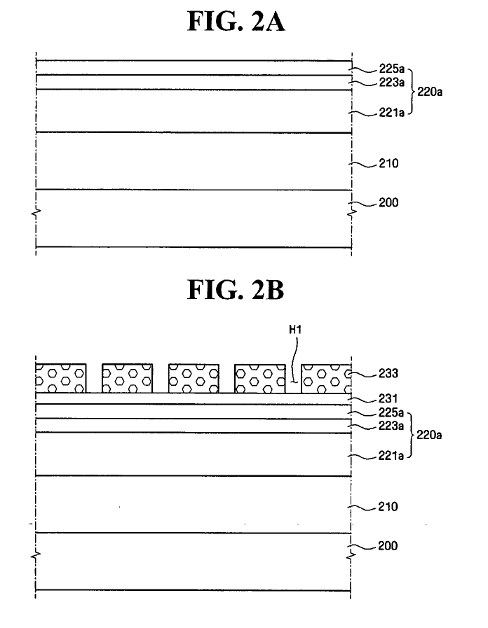

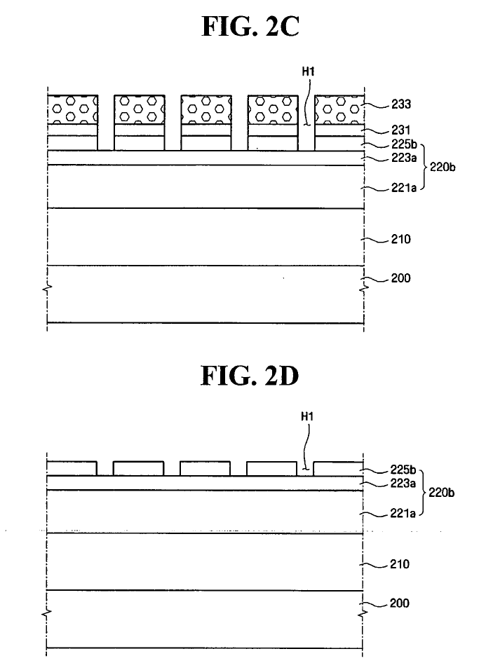

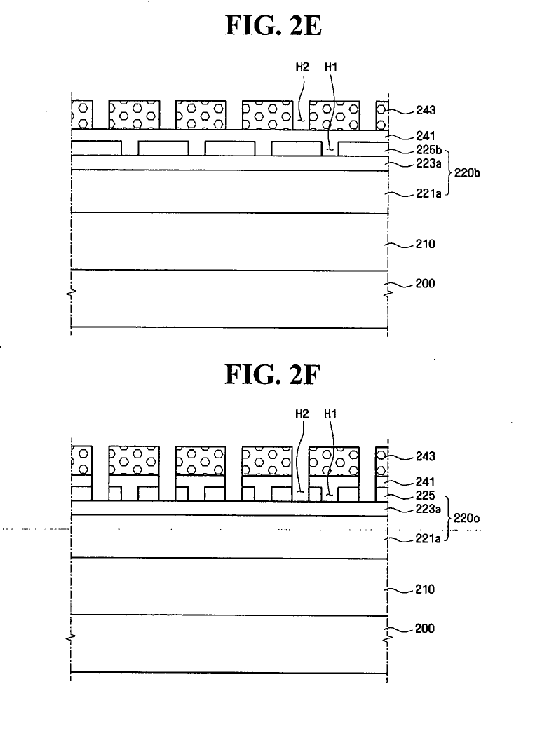

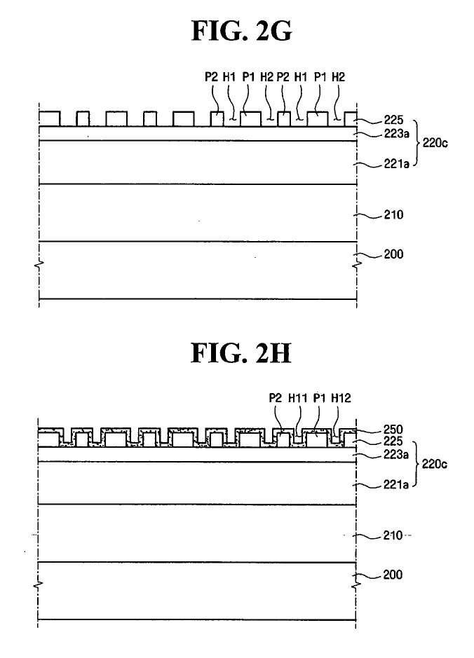

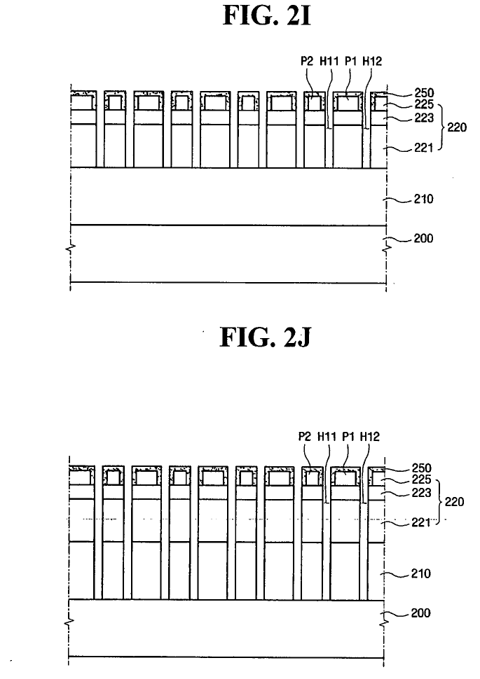

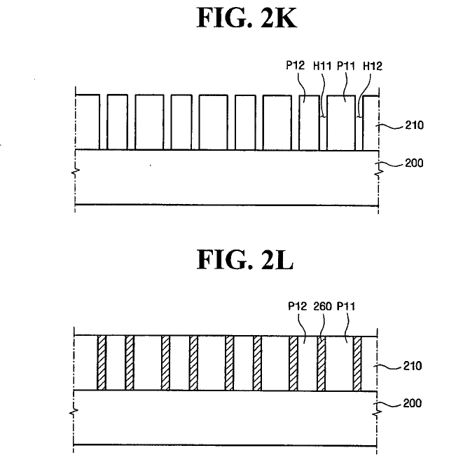

Hereinafter, another embodiment of a method of fabricating a semiconductor device according to aspects of the present invention will be described with reference to FIGS. 2A through 2L. Processes that are substantially the same as those described with reference to FIGS. 1A through 1K will not be described again or will be described briefly to avoid repetition, and the following description will focus on differences with the foregoing description with reference to FIGS. 1A through 1K.

First, as illustrated in FIG. 2A, an interlayer insulating layer 210 and a hard mask layer 220a are sequentially formed on a semiconductor substrate. The hard mask layer 220a is formed of a multi-layered structure in which a first hard mask layer 221a, a second hard mask layer 223a, and a third hard mask layer 225a are sequentially deposited.

Here, the first hard mask layer 221a, the second hard mask layer 223a, and the third hard mask layer 225a can be formed of materials having different etching selectivities. For example, the first hard mask layer 221a can be an amorphous carbon layer, the second hard mask layer 223a can be an oxide layer such as a PETEOS layer, and the third hard mask layer 225a can be a silicon oxy-nitride layer, as examples. By forming the hard mask layer 220a as a multi-layered structure, hard mask layers in a lower portion can be etched using a hard mask layer pattern formed in an upper portion, thereby reducing the thickness of a photoresist pattern for patterning the hard mask layer 220a. Thus, a short-wavelength light source such as ArF can be efficiently used. Although a hard mask layer having a three-layered structure is taken as an example in the current embodiment, a hard mask layer having a two or more-layered structure is within the scope of the present invention.

When the first hard mask layer 221a is an amorphous carbon layer, a PETEOS layer used as the second hard mask layer 223a can be used as a capping layer for the amorphous carbon layer. The first hard mask layer 221a can be formed with a thickness of about 2000 Å, the second hard mask layer 223a can be formed with a thickness of about 700 Å, and the third hard mask layer 225a can be formed with a thickness of about 600 Å, in this embodiment. However, in accordance with aspects of the present invention these thicknesses can be increased or decreased according to the thickness or material of the interlayer insulating layer 210 to be formed and etched under the hard mask layer 220a.

Referring to FIG. 2B, a first photoresist pattern 223 and a first anti-reflective layer 231 are formed to pattern the third hard mask layer 225a that is the top layer of the hard mask layer 220a.

As illustrated in FIG. 2C, the third hard mask layer (225a of FIG. 2B) is primarily patterned using the first photoresist pattern 233 as an etching mask, thereby forming a first contact hole pattern H1 in the third hard mask layer 225b.

After the first photoresist pattern 233 and the first anti-reflective layer 231 are removed by a generally known method, as illustrated in FIG. 2D, a second anti-reflective layer 241 is formed to cover the third hard mask layer 225b in which the first contact hole pattern H1 is formed, and a second photoresist pattern 243 for forming a second contact hole pattern H2 is formed, as illustrated in FIG. 2E. The second contact hole pattern H2 formed by the second photoresist pattern 243 can be interspersed with the first contact hole pattern H1 formed in the third hard mask layer 225b.

As illustrated in FIG. 2F, the third hard mask layer 225b is patterned a second time using the second photoresist pattern 243 as an etching mask. Thus, a third hard mask pattern 225 including the first contact hole pattern H1 and the second contact hole pattern H2 is completed.

Here, the first contact hole pattern H1 and the second contact hole pattern H2 can be interspersed with each other, e.g., in an alternating pattern, as described with reference to FIGS. 1A through 1K. Also, as illustrated in FIG. 2F, the distance between the first contact hole pattern H1 and the second contact hole pattern H2 need not be uniform. This can be intentional due to the layout of a contact hole pattern of a semiconductor device or can be caused by misalignment during formation of the second contact hole pattern H2.

Next, as illustrated in FIG. 2G, the third hard mask pattern 225 is exposed by removing the second photoresist pattern 243 and a second anti-reflective layer 241 by a general ashing and strip process, for example. The third hard mask pattern 225 is used as an etching mask for the first hard mask layer 221a and the second hard mask layer 223a under the third hard mask pattern 225.

As illustrated in FIG. 2G, the first contact hole pattern H1 and the second contact hole pattern H2 are interspersed with each other and a first pattern P1 and a second pattern P2 having different widths can be positioned between the first contact hole pattern H1 and the second contact hole pattern H2.

As illustrated in FIG. 2H, a supporting liner layer 250 is formed conformally on the third hard mask pattern 225. The supporting liner layer 250 can support the third hard mask pattern 225 during a subsequent etching process. Thus, collapse of the third hard mask pattern 225 during etching of the hard mask layers 231a and 233a under the third hard mask pattern 225 can be prevented, thereby stably forming a hard mask pattern. Here, the supporting liner layer 250 can be formed of a material included in a family having a similar etching selectivity to the second hard mask layer 223a. The widths of the first contact hole pattern H11 and the second contact hole pattern H12 are reduced by forming the supporting liner layer 250.

As illustrated in FIG. 2I, the second hard mask layer 223a and the first hard mask layer 221a are sequentially patterned using the third hard mask pattern 225 having the supporting liner layer 250 as an etching mask, thereby completing the hard mask pattern 220.

As illustrated in FIG. 2J, the interlayer insulating layer 210 is patterned using the hard mask pattern 220 as an etching mask. Thus, the interlayer insulating layer 210 including the first contact hole pattern H11 and the second contact hole pattern H12 can be formed.

As illustrated in FIG. 2K, the hard mask pattern 220 is removed by a generally known method, thereby exposing the top of the interlayer insulating layer 210.

As illustrated in FIG. 2L, contact plugs 260 are formed by filling the plurality of formed contact hole patterns with a conductive material, thereby completing a contact in the interlayer insulating layer 210.

A semiconductor device can be completed by forming interconnections for enabling input/output of an electric signal, forming a passivation layer on a substrate, and packaging the substrate, according to processes well known to those skilled in the field of semiconductor devices. Those processes, being generally known, will not be described.

As described above, according to aspects of the present invention, by forming a hard mask pattern that is prevented from collapsing, a contact hole pattern can be formed stably in an interlayer insulating layer and short-circuits between contacts can be minimized.

While the present invention has been particularly shown and described with reference to exemplary embodiments of various aspects thereof, it will be understood by those of ordinary skill in the art that various changes in form and details can be made therein without departing from the spirit and scope of the present invention, which is defined by the following claims. Therefore, it is to be understood that the above-described embodiments have been provided only in a descriptive sense and will not be construed as placing any limitation on the scope of the invention. It is intended by the following claims to claim that which is literally described and all equivalents thereto, including all modifications and variations that fall within the scope of each claim.

What is claimed is:

1. A method of fabricating a semiconductor device, the method comprising:
forming an interlayer insulating layer on a semiconductor substrate;
forming a hard mask layer on the interlayer insulating layer;
forming a hard mask pattern in which a plurality of contact hole patterns are formed by patterning the hard mask layer at least two times;
conformally forming a supporting liner layer on the hard mask pattern, which supports the hard mask pattern during etching by reinforcing the thickness of the hard mask pattern;
forming a plurality of contact hole patterns in the interlayer insulating layer using the hard mask pattern on which the supporting liner layer is formed as an etching mask; and
forming contact plugs filling the plurality of contact hole patterns.

2. The method of claim 1, wherein the forming of the hard mask layer comprises forming a hard mask layer having a multi-layered structure on the interlayer insulating layer.

3. The method of claim 1, wherein the forming of the hard mask layer comprises forming a silicon oxide layer, a silicon nitride layer, a silicon oxy-nitride layer, or an amorphous carbon layer.

4. The method of claim 1, wherein the supporting liner layer is formed using atomic layer deposition (ALD) or plasma enhanced chemical vapor deposition (PECVD).

5. The method of claim 1, wherein the contact hole patterns are formed with a width of about 50 nm or less.

6. The method of claim 1, wherein the contact hole patterns are formed such that a distance between the contact hole patterns is about 50 nm or less.

7. The method of claim 1, wherein the forming of the hard mask pattern comprises:
forming a plurality of first contact hole patterns that are separated by a predetermined distance from each other by performing a first patterning process; and
forming second contact hole patterns between the first contact hole patterns by performing a second patterning process.

8. The method of claim 1, wherein the forming of the hard mask pattern comprises:
forming a first anti-reflective layer on the hard mask layer;
forming on the anti-reflective layer a first photoresist pattern that exposes the top of the anti-reflective layer and has the first contact hole pattern formed therein;
forming the plurality of first contact hole patterns separated by a predetermined distance in the hard mask layer using the first photoresist pattern as an etching mask;
removing the first photoresist pattern and the first anti-reflective layer, and forming a second anti-reflective layer covering the hard mask layer in which the first contact hole pattern is formed;
forming a second photoresist pattern that exposes the top of the second anti-reflective layer and in which the second contact hole patterns interspersed with the plurality of first contact hole patterns are formed; and
forming the second contact hole pattern in the hard mask layer in which the first contact hole patterns are formed using the second photoresist pattern as an etching mask.

9. A method of fabricating a semiconductor device, the method comprising:
forming an interlayer insulating layer on a semiconductor substrate;
forming a hard mask layer having a multi-layered structure on the interlayer insulating layer;
forming a top mask pattern layer in which a plurality of contact hole patterns are formed by patterning the top layer of the hard mask layer at least two times;
conformally forming on the top mask pattern layer a supporting liner layer that supports the top mask pattern layer during etching by reinforcing the thickness of the top mask patter layer;
completing the hard mask pattern having the multi-layered structure by patterning the top mask pattern layer in which the supporting liner layer is formed using an etching mask;
forming a plurality of contact hole patterns in the interlayer insulating layer using the hard mask pattern using an etching mask; and
forming contact plugs that fill the plurality of contact hole patterns.

10. The method of claim 9, wherein the forming of the hard mask layer comprises forming a silicon oxide layer, a silicon nitride layer, a silicon oxy-nitride layer, or an amorphous carbon layer.

11. The method of claim 9, wherein the forming of the supporting liner layer comprises forming the supporting liner layer using atomic layer deposition (ALD) or plasma enhanced chemical vapor deposition (PECVD).

12. The method of claim 9, wherein the forming of the contact hole patterns comprises forming the contact hole patterns with a width of about 50 nm or less.

13. The method of claim 9, wherein the forming of the contact hole patterns comprises forming the contact hole patterns such that a distance between the contact hole patterns is about 50 nm or less.

14. The method of claim 9, wherein the forming of the top mask pattern layer comprises:
forming a plurality of first contact hole patterns separated by a predetermined distance by performing a first patterning process on the top layer of the hard mask layer; and
forming second contact hole patterns between the plurality of first contact hole patterns by performing a second patterning process on the top layer of the hard mask layer in which the first contact hole patterns are formed.

15. The method of claim 9, wherein the forming of the top hard mask pattern comprises:
forming a first anti-reflective layer on the top layer of the hard mask layer;
forming on the first anti-reflective layer a first photoresist pattern that exposes the top of the first anti-reflective layer and in which the first contact hole patterns are formed;
forming the plurality of first contact hole patterns separated by a predetermined distance in the top layer of the hard mask layer using the first photoresist pattern as an etching mask;
removing the first photoresist pattern and the first anti-reflective layer;
forming a second anti-reflective layer covering the top layer of the hard mask layer in which the first contact hole patterns are formed;
forming a second photoresist pattern that exposes the top of the second anti-reflective layer and in which second contact hole patterns interspersed with the first contact hole patterns are formed; and
forming the second contact hole pattern in the top layer of the hard mask layer in which the first contact hole patterns are formed using the second photoresist pattern as an etching mask.
